(19) United States
(12) Patent Application Publication
(10) Pub. No.: US 2026/0043847 A1
(43) Pub. Date: Feb. 12, 2026

(54) BURN-IN BOARD AND BURN-IN SYSTEM

(71) Applicant: Expert International Mercantile Corporation, Hsinchu (TW)

(72) Inventors: Wei-Chih Sun, Hsinchu (TW); Yi-Hao Hong, Hsinchu (TW)

(21) Appl. No.: 18/969,490

(22) Filed: Dec. 5, 2024

(30) Foreign Application Priority Data
Aug. 8, 2024 (TW) 113129787

(51) Int. Cl. G01R 31/28

(52) U.S. Cl. CPC G01R 31/2879; G01R 31/2863

(57) ABSTRACT

Provided is a burn-in board including: a plurality of test sockets each configured to receive a device under test and including at least one socket power module; and at least one signal test board coupled to the burn-in board, being in signal connection with at least one of the plurality of test sockets of the burn-in board, and adapted to receive a signal correlating with a power supply setting. The signal test board controllably causes the burn-in board to provide power to at least one of the plurality of test sockets according to the signal to perform a test process. The at least one socket power module has a power compensation mechanism for ensuring that the devices under test receive the power equally.

### RELATED APPLICATIONS

This application claims priority to Taiwan Application Serial Number 113129787, filed on Aug. 8, 2024, which is incorporated by reference herein in its entirety.

### BACKGROUND OF THE INVENTION

### Field of the Invention

The present disclosure relates to devices for use on burn-in boards and burn-in systems, and more particularly to a burn-in system applicable to different transmission interfaces and a device with a power compensation mechanism.

### Description of the Prior Art

In semiconductor or PCB industry, burn-in is a process of testing wafers or chips, allowing a plurality of wafers or chips to be mounted on test stations on a burn-in board to undergo various tests on parameters, such as temperature, stress and frequency, to detect any failure caused by a defect related to design, materials, processes or manufacturing in a subsequent manufacturing process.

The burn-in boards used by manufacturers nowadays are customized according to clients' product requirements. Thus, every instance of emergence of the demand for a burn-in test to be performed on a new product always necessitates manufacturing burn-in boards with corresponding new test criteria anew. Furthermore, depending on different test items or parameters, wafers or chips have to be disposed on separate burn-in boards in order to undergo tests, rendering the overall test process flow time-consuming. Therefore, it is important for clients to address the aforesaid issues efficiently and reduce the manufacturing cost of burn-in boards while testing a wide range of frequencies of products within a specific period of time.

FIG. 1 schematically illustrates a conventional burn-in board 710 that has a signal interface 140 and a power interface 150 for receiving test signals (for example, 10 MHz signals) for use in a burn-in test and power signals for use in the operation of the entire burn-in board respectively. The burn-in board 710 further has an array of a plurality of test sockets 120 each adapted to receive a device under test (DUT), for example, a chip. The signal interface 140 and the power interface 150 constitute a combination of various connectors and electronic components and are configured to transmit signals to the test sockets 120 along specific electrical conduction paths. However, the aforesaid configuration has some drawbacks harmful to test consistency. The burn-in board 710 usually has a considerable large area. The signal interface 140 and the power interface 150 are usually disposed at an edge of the burn-in board 710. The length of the electrical conduction paths from the test sockets 120 to the interfaces 140, 150 depends on the positions of the test sockets 120 relative to the burn-in board 710. Therefore, identical signals arrive at different test sockets 120 at different points in time, and long electrical conduction paths not only lead to signal loss to the detriment of test quality but also undermine the stability of the power supply status remote from the power interface 150. However, owing to the aforesaid configuration, one single burn-in board can only simultaneously provide one single test to all DUTs; as a result, upper limits of test signals or other test schedules conducive to enhancement of test efficiency are subjected to limitation and thus rendered useless.

Therefore, it is imperative to provide a better way to improve the prior art in terms of the reduction of signal loss, the optimization of various test schedules, the augmentation of the upper limits of test signals, and the enhancement of its applicability to various transmission interfaces.

### SUMMARY OF THE INVENTION

In view of the aforesaid drawbacks of the prior art, it is an objective of the disclosure to provide an apparatus that is applicable to a burn-in board, has a power compensation mechanism, and ensure that all devices under test receive the same, stable electric power. Another objective of the disclosure is to provide a signal test board applicable to different test environments and different transmission interfaces and effective in controlling a burn-in board and different parameters to enable the devices under test to be tested in terms of many different parameters.

To achieve the above and other objectives, the disclosure provides a burn-in board, comprising: a plurality of test sockets each configured to receive a device under test and each comprising at least one socket power module; and at least one signal test board coupled to the burn-in board, being in signal connection with at least one of the plurality of test sockets of the burn-in board, and adapted to receive a signal correlating with a power supply setting, wherein the signal test board controllably causes the burn-in board to provide power to at least one of the plurality of test sockets according to the signal to perform a test process, wherein the at least one socket power module has a power compensation mechanism for ensuring that the devices under test receive the power equally.

To achieve the above and other objectives, the disclosure provides a burn-in board, comprising: a plurality of test sockets each configured to receive a device under test; at least one signal test board coupled to the burn-in board, being in signal connection with at least one of the plurality of test sockets of the burn-in board, and adapted to receive a signal correlating with a power supply setting; and a plurality of socket power modules, wherein the test sockets are each electrically connected to at least one of the socket power modules, wherein the signal test board controllably causes the burn-in board to provide power to at least one of the plurality of test sockets according to the signal to perform a test process, wherein the at least one socket power module has a power compensation mechanism for ensuring that the devices under test receive the power equally.

In the burn-in board, the socket power module further has a power detection component configured to detect a power transmitted to the devices under test, and the socket power module adjusts the power transmitted from the socket power module to the devices under test according to a first difference lying between the power transmitted from the socket power module to the devices under test and supply setting of the power and detected by the power detection component.

In the burn-in board, the socket power module is an integrated power module or a power management integrated circuit.

In the burn-in board, the socket power module has a socket detection module electrically connected to the devices under test and the signal test board and configured to detect a power during a test performed on the devices under test, and the signal test board adjusts power supply to the test sockets according to a second difference lying between each of the devices under test and supply setting of the power and detected by the socket detection module, allowing the socket detection module to transmit the second difference to the signal test board.

To achieve the above and other objectives, the disclosure provides a burn-in system, integrated into a signal test board, the system comprising: a control unit configured to perform programming according to a plurality of transmission interfaces to output a test signal corresponding to one of the plurality of transmission interfaces and receive a control signal from a signal control system; a memory unit; a multiport unit in signal connection with a plurality of test sockets; a communication unit in signal connection with the control unit, the memory unit and the multiport unit, wherein the control unit outputs a test signal to at least one of the plurality of test sockets according to the control signal.

To achieve the above and other objectives, the disclosure provides a burn-in system, integrated into a signal test board, the system comprising: a memory unit; a multiport unit in signal connection with a plurality of test sockets; a communication unit being in signal connection with the memory unit and the multiport unit, configured to perform programming according to a plurality of transmission interfaces to output a test signal corresponding to one of the plurality of transmission interfaces, and adapted to receive a control signal from a signal control system, wherein the communication unit outputs a test signal to at least one of the plurality of test sockets according to the control signal.

The burn-in board further comprises a conversion unit configured to be in signal connection with the test sockets of one of the plurality of transmission interfaces.

In the burn-in board, the plurality of transmission interfaces at least comprise one of PCIe, SATA, and USB.

### BRIEF DESCRIPTION OF THE DRAWINGS

FIG. 1 (PRIOR ART) is a block diagram of a conventional burn-in device.

FIG. 2 is a block diagram of a processor burn-in device 100 capable of performing functional tests according to the disclosure.

FIG. 3 is a block diagram of the burn-in device mounted on a burn-in test machine according to the disclosure.

FIG. 4a is a bottom view of the burn-in device and a connector according to the disclosure.

FIG. 4b is a lateral view of the burn-in device and the connector according to the disclosure.

FIG. 5 is a schematic view of a signal test board connected to test sockets according to the disclosure.

FIG. 6 is a block diagram of a signal path according to the disclosure.

FIG. 7 is a block diagram of the signal test board and a device under test according to the disclosure.

FIG. 8 is a block diagram of a burn-in board with a power compensation mechanism according to the disclosure.

FIG. 9A is a schematic view of a socket power module of the disclosure.

FIG. 9B is a block diagram of a socket detection module of the disclosure.

FIG. 10 is a block diagram of a burn-in system of the disclosure.

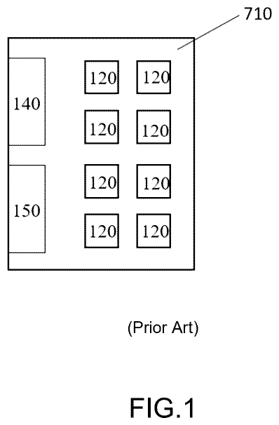

### DETAILED DESCRIPTION OF THE EMBODIMENTS

All embodiments of the disclosure are described below and illustrated by schematic diagrams depictive of ideal embodiments of the disclosure. The shapes and arrangement shown in the diagrams depend on manufacturing technology, design and/or tolerance. Therefore, the embodiments of the disclosure shall not be construed to restrict structural features of the disclosure to specific components or shapes but shall be construed to embody any shape-related differences arising from a manufacturing process.

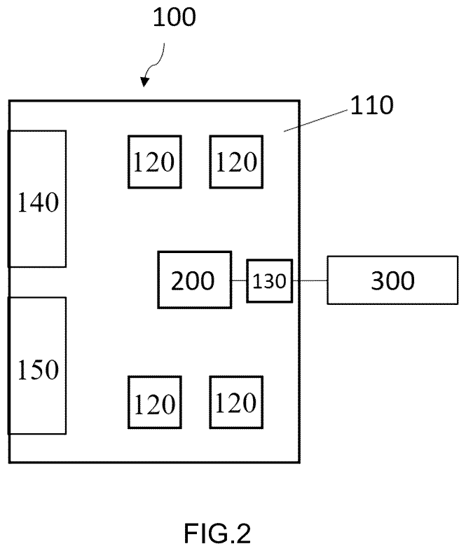

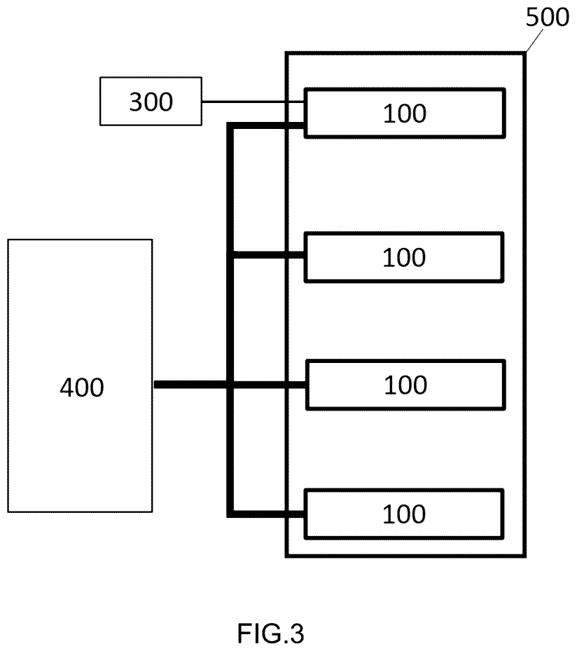

For the sake of comprehension of the disclosure, a processor burn-in device capable of performing functional tests according to the disclosure is concisely described below. FIG. 2 is a block diagram of a processor burn-in device 100 capable of performing functional tests according to the disclosure. FIG. 3 is a block diagram of the processor burn-in device mounted on a burn-in test machine according to the disclosure. The processor burn-in device 100 capable of performing functional tests essentially comprises a burn-in board 110. The burn-in board 110 has a plurality of test sockets 120. The test sockets 120 each comprise a device under test. The burn-in board 110 also has a signal interface 140 and a power interface 150 for receiving test signals for use in a burn-in test and power signals for enabling the burn-in board 110 to operate respectively. Burn-in test boards are well known among persons skilled in the art. Unlike the burn-in test boards, the disclosure provides a signal test board 200 detachably disposed on the burn-in board 110 and/or in signal connection with an external signal control system 300 through a sub-system module 130 to allow the burn-in board 110 to control different parameters of the signal test board 200 through the input setting of the signal control system 300 to perform a burn-in test. As shown in FIG. 3, the signal control system 300 is connected only to the uppermost processor burn-in device 100 capable of performing functional tests. However, in practice, the signal control system 300 is connected to each processor burn-in device 100 capable of performing functional tests in FIG. 3. For example, the signal test board 200 is a circuit for providing high-frequency test signals. A specific way of connecting the signal test board 200 of the disclosure is described later. For the sake of comprehension, the description herein is based on frequency parameters, and thus the signal test board 200 is not restricted to controlling frequency but may also be applicable to any other test-required parameters, such as temperature and stress, as well as controlling a plurality of test-required parameters. The signal control system 300 is an external computer apparatus that, together with the sub-system module 130, transmits signals through a universal interface, such as Ethernet. The processor burn-in device 100 capable of performing functional tests is connected to a test apparatus 400 of a test chamber exterior 500 of FIG. 3. The test apparatus 400 provides a signal through the signal interface 140 of the burn-in board 110, and the signal is sent to the signal test board 200. The sub-system module 130 and the signal test board 200 together perform the function setting as follows: 1. update the setting of the signal test board 200 for testing high-frequency programs; 2. update the firmware of an FPGA in the signal test board 200. The test apparatus 400 has a power 410 for providing required power to the burn-in board 110 through the power interface 150 of the burn-in board 110.

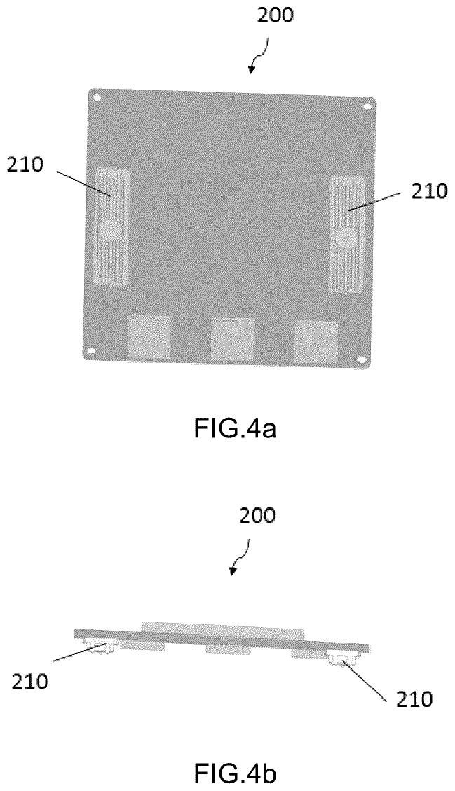

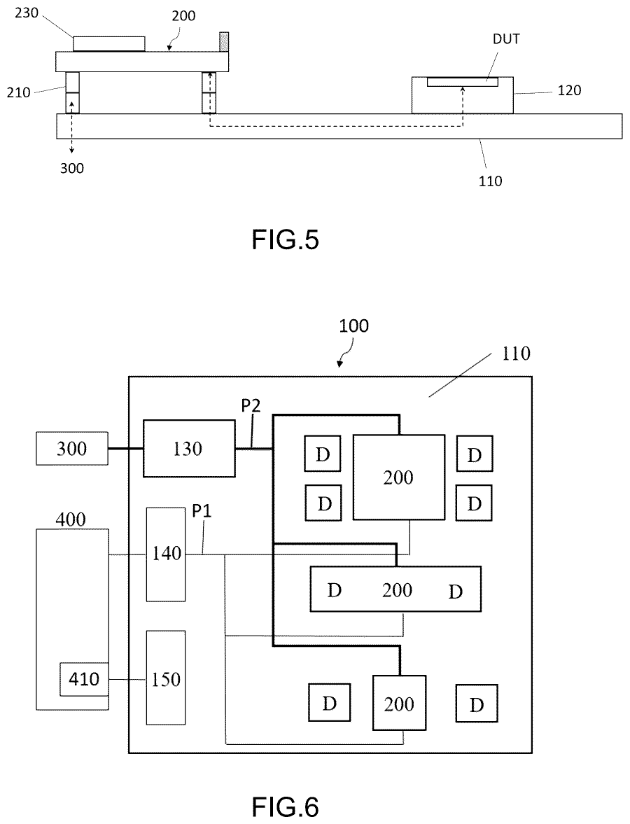

FIG. 4a and FIG. 4b are a bottom view and a lateral view of the signal test board 200 of the disclosure respectively. FIG. 5 is a schematic view of the signal test board 200 connected to the burn-in board 110 according to the disclosure. The signal test board 200 has a communication interface in signal connection with the signal control system 300 and a circuit assembly for outputting test signals, distributed on the top surface of the signal test board 200. At least one first connector 210 is fixedly disposed on the bottom surface (i.e., the surface facing the burn-in board 110) of the signal test board 200, and a connector or socket (as shown in FIG. 5) corresponding in position to the first connector 210 is disposed on a top surface (i.e., the surface shared by the burn-in board 110 and each of the test sockets 120) of the burn-in board 110, for example, using a board-to-board connector. The choice of the aforesaid arrangement depends on the wiring layout of the burn-in board 110. Owing to the first connector 210, the signal test board 200 is like a mezzanine board disposed on the burn-in board 110 and adapted to form electrical connection and signal connection. With the signal test board 200 being like the mezzanine board, the test sockets 120 are disposed between the burn-in board 110 and the signal test board 200. The diagrams merely show one signal test board 200, but multiple signal test boards 200 are feasible. The signal test boards 200 are connected to the test sockets 120 respectively to perform tests on a portion of devices under test (DUTs). The way of positioning the first connector 210 in place depends on how the first connector 210 is in electrical connection and signal connection with the burn-in board 110 and thus is not restricted to what is shown in FIG. 4a and FIG. 4b. For example, the first connector 210 can be provided in the number of one and centrally positioned. Furthermore, the disclosure is not restrictive of the orientation of the first connector 210. A control component 230 is mounted on the top surface (i.e., the surface opposing the burn-in board 110) of the signal test board 200. The control component 230 is a field programmable gate array (FPGA) or a central processing unit (CPU) and is essentially intended to create test-required high-frequency programs. On the whole, the signal test board 200 receives signals of the signal control system 300 and sends a test signal to a plurality of the test sockets 120 to perform tests. Furthermore, the signal test board 200 receives, integrates and sends data fed back from the test sockets 120 of the burn-in board 110 to the signal control system 300.

In a specific embodiment illustrated by FIG. 5, which is a schematic view of the signal test board 200 connected to the test sockets 120 according to the disclosure, the signal test board 200 and the test sockets 120 are configured to be in signal connection with each other through a first connector 210 to allow the signal test board 200, the signal control system 300 (and/or the sub-system module 130) and the test sockets 120 to be in signal connection with each other, wherein the first connector 210 is, for example, a board-to-board connector. For instance, the first connector 210 is connected to the burn-in board 110 to control how signals work to allow the signal test board 200 to transmit signals at a transmission speed of 10 MHz to the test sockets 120, allowing a burn-in test to be performed on a device under test (DUT).

The processor burn-in device 100 capable of performing functional tests according to the disclosure is described in detail below. Referring to FIG. 6, control signal path P1 (depicted as the thinner path) is a path whereby the test apparatus 400 sends/receives control signals to/from the control component 230 in the signal test board 200. The test apparatus 400 transmits a 10 MHz signal for triggering the signal test board 200 to perform a burn-in process on each burn-in module. The burn-in process entails modifying various burn-in modules (for example, high-temperature modules and high-voltage modules) mounted on the burn-in board 110 to meet its different test needs or to test different parameters. The burn-in process uses the 10 MHz signal to control the burn-in modules. Alternatively, the burn-in modules are built-in modules disposed in the signal test board 200, allowing the signal test board 200 to control the burn-in modules. Test parameter setting signals are transmitted along test parameter setting signal path P2 (depicted as the thicker path shown in FIG. 5) through a graphical user interface (GUI) on the signal control system 300 to adjust the setting of the sub-system module 130.

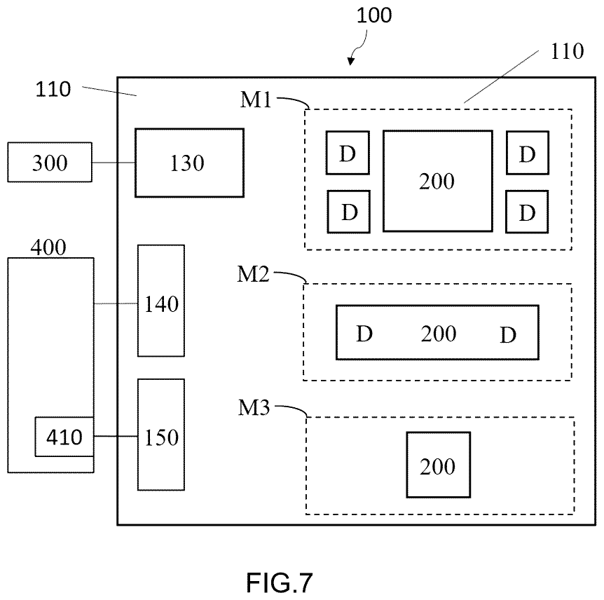

The relationship between the signal test board 200 and a device under test D is described below. Referring to FIG. 7, there is shown a block diagram of a burn-in board of the processor burn-in device capable of performing functional tests and a device under test according to the disclosure, where M1˜M3 denote different embodiments of the relationship between the signal test board 200 and the device under test D in the test socket. M1 embodiment is the same as the embodiment illustrated by FIG. 4a and FIG. 4b in that the signal test board 200 is fixed to the burn-in board 110 and is in signal connection with multiple devices under test D, allowing the signal test board 200 to perform a burn-in test on multiple devices under test D. In M2 embodiment, the devices under test D and the signal test board 200 are disposed on the same board and then jointly mounted on the burn-in board 110 to undergo a burn-in test. In M3 embodiment, the signal test board 200 is like a mezzanine board for performing a burn-in test on a device under test D (with the device under test D disposed in the test socket 120, disposed between the signal test board 200 and the burn-in board 110, and thus invisible in M3 embodiment.) Therefore, in M3 embodiment, each device under test D can be customized to be connected to a signal test board 200. Thus, the signal test board 200 can be customized to be of any size and disposed on the burn-in board 110, dispensing with the need to design the burn-in board 110 anew, thus reducing manufacturing cost and wiring layout complexity.

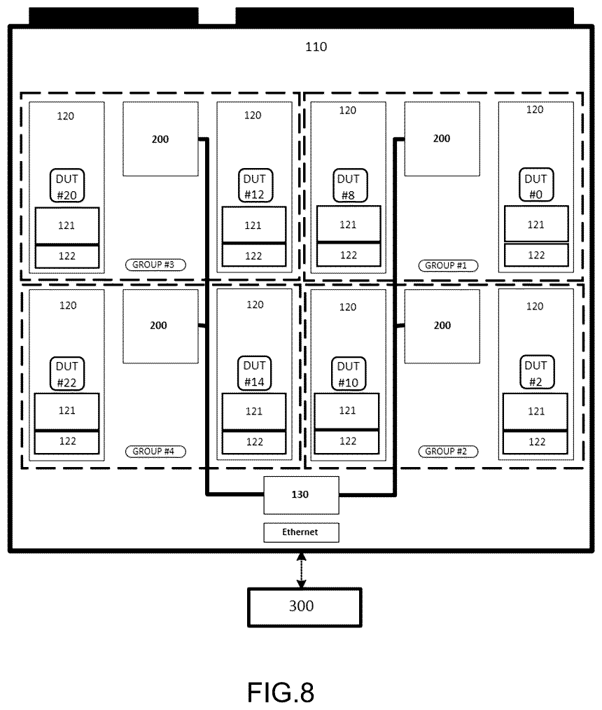

The second embodiment of the disclosure is illustrated by FIG. 8 which is a block diagram of a burn-in board with a power compensation mechanism according to the disclosure, with the second embodiment being based on M3 embodiment above. In the second embodiment, the burn-in board 110 comes with a plurality of test sockets 120 each having at least one socket power module 121 and at least one socket detection module 122, wherein FIG. 8 shows that DUTs (devices under test) are disposed in the test sockets 120 respectively, and shows that the signal test boards 200 are disposed on the test sockets 120 respectively. Therefore, as shown in FIG. 8, each signal test board 200 simultaneously controllably causes two test sockets 120 to provide power to two corresponding devices under test (DUTs). For example, as shown in FIG. 8, the signal test board 200 of GROUP #1 simultaneously controllably causes the test sockets 120 to provide power to DUT #0 and DUT #8 to undergo a test.

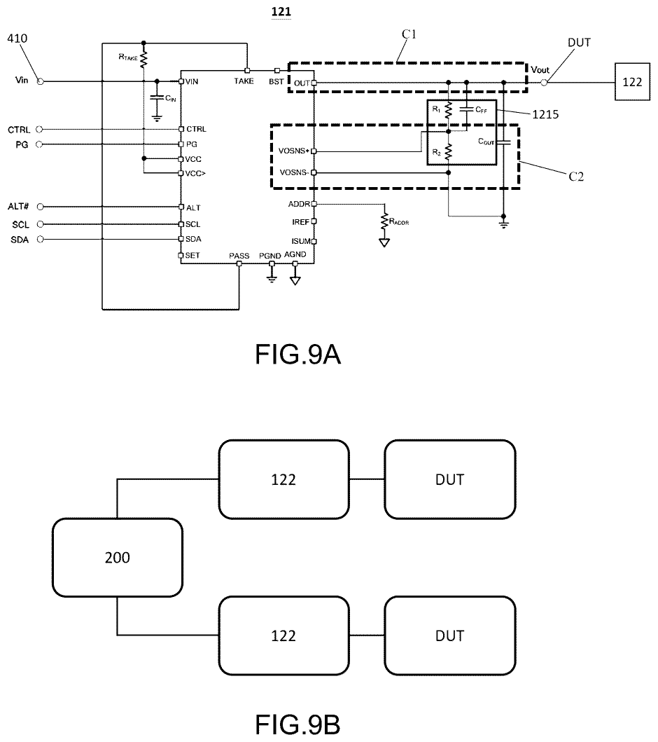

FIG. 9A is a schematic view of a socket power module of the disclosure. As shown in the diagram, during the burn-in test, the test sockets 120 distal to a power supply end (not shown) of the burn-in board 110 have relatively long power supply wirings and relatively huge loss and thus receive inadequate, unstable power. Therefore, the power compensation mechanism of the socket power module 121 ensures that the devices under test receive power equally. Referring to FIG. 9A, the socket power module 121 further has a power detection component 1215 electrically connected between the socket power module 121 and the device under test (DUT) to detect the power (path in zone C1) being transmitted to the device under test (DUT). When the power detection component 1215 detects a first difference between the power transmitted from the socket power module 121 to the device under test (DUT) and a power supply setting, the power detection component 1215 transmits a compensation signal about the first difference to the socket power module 121 (path in zone C2); then, the socket power module 121 processes the compensation signal through a power conversion (DC converter) IC to allow the socket power module 121 to adjust, according to the first difference, the power transmitted from the socket power module 121 to the device under test (DUT). For instance, when the socket power module 121 receives electric power from the power 410 and outputs a voltage of 1V, according to the signal of the power supply setting, to the device under test (DUT) to perform tests, the power detection component 1215 detects, according to VOSNS+ and VOSNS− shown in FIG. 9A, whether the voltage transmitted from the socket power module 121 to the device under test (DUT) is different from the power supply setting. When the power detection component 1215 detects a first difference between the voltage and the parameters of the power supply setting, for example, a detected voltage of 0.8V indicates a first difference of 0.2V, and thus the power detection component 1215 transmits a compensation signal about the first difference to the socket power module 121 to allow the socket power module 121 to process the compensation signal through a power conversion IC. Finally, the voltage transmitted from the socket power module 121 to the device under test (DUT) is adjusted according to the first difference of 0.2V to become 1.2V. Therefore, the aforesaid mechanism is effective in overcoming the drawback of a wiring-induced voltage loss of 0.2V causing the device under test (DUT) to receive a voltage of around 1.0V and the drawback of the devices under test (DUT) receiving different power because of different loss. Therefore, the aforesaid voltage loss compensation mechanism enables all the devices under test (DUT) in the test sockets 120 to receive the same voltage. The socket power module 121 further has a voltage stabilization mechanism for fine-tuning a voltage to stabilize the voltage, for example, in the event of an abrupt increase of current and a decrease of voltage as a result of different load variations. In a specific embodiment of the disclosure, the socket power module 121 is a DC/DC converter, an integrated power module, a power management integrated circuit or a module or a combination of modules having the same function as the socket power module, which is capable of integrating multiple power management functions in power management application to facilitate designing and simplifying a power management system.

Referring to FIG. 9B, there is shown a block diagram of a socket detection module of the disclosure. Each socket detection module 122 is electrically connected to the device under test (DUT) and the signal test board 200. The socket detection module 122 detects the power of the device under test (DUT) during a test and detects whether the power conforms with parameters (i.e., the supply setting of power) of test signals. When the socket detection module 122 detects that the device under test (DUT) differs from the parameters of the test signals, the socket detection module 122 detects a second difference between the voltage of the device under test (DUT) and the parameters of the test signals and transmits the second difference to the signal test board 200, allowing the signal test board 200 to adjust the power supply of the test sockets 120 according to the second difference. Since the voltage of each device under test (DUT) during a burn-in test is detected in real time by each socket detection module 122, the signal test board 200 can adjust the power supply of each test socket 120 according to the second difference of each device under test (DUT) to confirm that the devices under test (DUT) are tested under the same voltage during a burn-in test. In a specific embodiment, a user operates the signal control system 300 to transmit signals of the power supply setting to the sub-system module 130, and the sub-system module 130 transmits the signals to the signal test board 200, allowing the control component 230 of the signal test board 200 to enable each signal test board 200 to control the power of the test sockets 120 according to parameters of the power supply setting. Then, the socket detection module 122 uses an FPGA to detect whether the device under test (DUT) differs from parameters of the power supply setting (For example, the socket detection module 122 converts signals of the current or voltage of the device under test (DUT) into detected numerical values of the current or voltage and obtains the second difference between the detected numerical values and the output value of the power supply setting.) Then, the signal test board 200 adjusts the power supply to the test sockets 120 anew according to the second difference to compensate for the difference caused by a loss in the path of system hardware. Thus, the signal test board 200 ensures that the devices under test (DUT) in respective groups receive voltage equally. In a specific embodiment of the disclosure, when system hardware alters and thus causes a change in the impedance on a power path (as a result of, for example, changing a PCB, changing a socket or changing a component on the power path, but the disclosure is not limited thereto), the socket detection module 122 is conducive to the adjustment of the power supply to the test sockets 120 to compensate for the difference caused by a loss in the path of system hardware. In a specific embodiment of the disclosure, the socket detection module 122 is an analog-to-digital converter.

In another embodiment of the disclosure, the socket power module 121 and the socket detection module 122 are disposed on the burn-in board 110 but not disposed in the test sockets 120, and each of the test sockets 120 is electrically connected to at least one socket power module 121, allowing the signal test board 200 to controllably cause, according to the signals, the burn-in board 110 to provide power to at least one of the plurality of test sockets 120 to perform a test process. In another embodiment of the disclosure, since multiple power is provided to the device under test (DUT) during a burn-in test, each of the test sockets 120 provides stable power through detection between multiple socket power modules 121 corresponding to multiple power respectively.

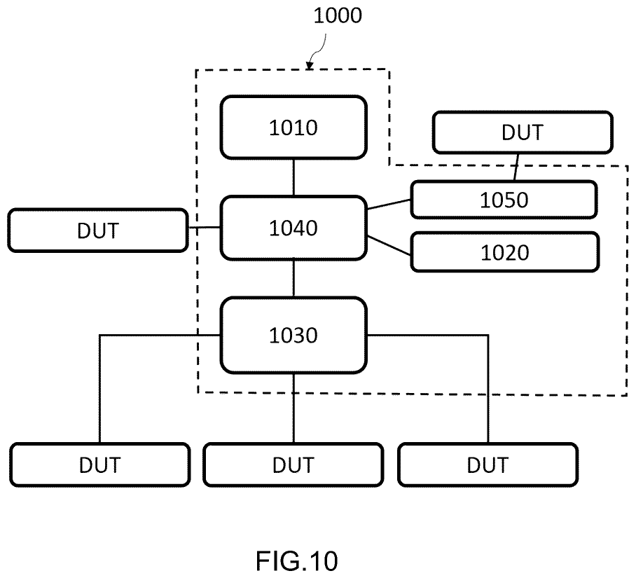

In the third embodiment of the disclosure, as illustrated by FIG. 10 which is a block diagram of a burn-in system 1000 of the disclosure. The burn-in system 1000 is applicable to a signal test board. The burn-in system 1000 comprises a control unit 1010, a memory unit 1020, a multiport unit 1030, a communication unit 1040 and a conversion unit 1050. The control unit 1010 is a CPU or FPGA configured to perform programming according to a plurality of transmission interfaces to output test signals corresponding to one of the plurality of transmission interfaces and receive a control signal from the signal control system 300 so as to process high-frequency signals and meet the need for data transmission. For instance, when the device under test (DUT) is a PCIe interface, the control unit 1010 performs programming anew according to firmware and wirings of the device under test (DUT), the test sockets 120 and the burn-in board 110 to allow the burn-in system 1000 to output test signals applicable to the PCIe interface. When the device under test (DUT) is a SATA interface, the control unit 1010 performs programming anew according to firmware and wirings of the device under test (DUT), the test sockets 120 and the burn-in board 110 to allow the burn-in system 1000 to output test signals applicable to the SATA interface. The memory unit 1020 stores data, searches for data, and controls signals, for example, programs of different transmission interfaces and their corresponding output test signals. The multiport unit 1030 is, for example, a PCIe switch in signal connection with a plurality of test sockets 120 to allow the plurality of test sockets 120 to share a port and thereby enable high-efficiency many-to-many communication. The communication unit 1040 is in signal connection with the control unit 1010, the memory unit 1020 and the multiport unit 1030. The communication unit 1040 is a Root Complex and an essential part of the burn-in system 1000 and manages communication signals in test environments, for example, functions as a bridge between the main memory of the system and each device, initializes and configures each device, manages data transmission, processes all read/write requests generated from the devices, and supports multiple ports each connected to a device or the multiport unit 1030. The conversion unit 1050 is, for example, a PCI-PCIe bridge provided as needed. The conversion unit 1050 connects a conventional interface device and a conversion device of a current-generation interface system to allow a conventional interface apparatus to be continuously in operation in interface environments. The control unit 1010 outputs a test signal to at least one of the plurality of test sockets 120 according to the control signal. A plurality of transmission interfaces for the plurality of test sockets 120 and the signal test board 200 at least include one of PCIe, SATA and USB or any other transmission interfaces applicable to the devices under test (DUTs) or the test sockets 120. The plurality of the devices under test (DUTs) serve as end points in a system framework.

On the whole, since conventional burn-in boards or signal test boards can perform burn-in tests on the devices under test only in accordance with test functions configured during a manufacturing process. However, as time goes by, test environments for the devices under test are becoming harsher, for example, in terms of test types and test upper limits. As a result, conventional burn-in boards and signal test boards have become unfitted, whereas signal test boards corresponding to the test sockets 120, the burn-in boards 110, and the devices under test for different transmission interfaces have to be changed. In view of the aforesaid drawbacks, the disclosure provides the burn-in system 1000 that forms a self-contained, system-scale, test-oriented signal test board. The burn-in system 1000 performs programming anew according to different devices under test and customer test needs in order to be applicable to the test sockets 120, the burn-in boards 110 and the devices under test for different transmission interfaces, transmit test signals corresponding to the transmission interfaces, convert and send customer-provided test patterns to the devices under test. Therefore, the burn-in system 1000 itself is a test system that can implement new test criteria merely through using existing burn-in board power supply systems and signal control systems. For instance, a conventional burn-in configuration performs a test on a test item within a specific period of time. For example, a lengthy burn-in test takes place in continuous and multiple patterns, and each test pattern lasts 168 to 1000 hours, and the conventional burn-in configuration can only perform one single test item (for example, voltage) in each test pattern. Therefore, in the pattern, it is difficult to detect those devices under test which respond negatively to the other test factors. In this regard, the burn-in system 1000 of the disclosure is a self-contained, system-scale, test-oriented signal test board that switches between patterns to other test items (for example, pressure) to detect as early as possible those devices under test which respond negatively. In another embodiment of the disclosure, a plurality of burn-in systems 1000 adjust schedules of different test items according to customer expectations.

In a variant of the third embodiment of the disclosure, the burn-in system 1000 comprises: a memory unit 1020; a multiport unit 1030 in signal connection with a plurality of test sockets 120; and a communication unit 1040 configured to perform programming according to a plurality of transmission interfaces to output test signals corresponding to one of the plurality of transmission interfaces, adapted to be in signal connection with the memory unit 1020 and the multiport unit 1030, and adapted to receive a control signal from the signal control system 300. In the variant of the third embodiment of the disclosure, the communication unit 1040 is a Root Complex, has functions of the control unit 1010, is configured to perform programming according to a plurality of transmission interfaces to output test signals corresponding to one of the plurality of transmission interfaces, is in signal connection with the memory unit 1020 and the multiport unit 1030, and outputs a test signal to at least one of the plurality of test sockets according to the control signal. In a specific embodiment of the disclosure, the control unit 1010 is a CPU or FPGA, and the communication unit 1040 is an FPGA. In a specific variant embodiment, the communication unit 1040 is a CPU or FPGA. In a specific embodiment of the disclosure, the control unit 1010 or the communication unit 1040 is connected to a hard disk drive, memory or flash memory.

Persons skilled in the art may apply various teachings of the disclosure to various burn-in test items. Various burn-in test items which the disclosure is applicable to are discussed as follows: 1. Open/Short Test, for verifying whether test-oriented signal pins are in contact with wafers or chips and detecting whether the signal pins have developed any short circuits relative to normal signal pins; 2. DC Parametric Test, for testing whether DC parameters of the wafers or chips conform with designed specifications, with the parameters, for example, exemplified by output drive current, current leakage, power current, and threshold level; 3. Functional Test, for verifying whether the wafers or chips correctly execute their anticipated logical functions and create test vectors or truth table to detect any malfunctioning in the wafers or chips; 4. AC Parametric Test, for ensuring that the wafers or chips can comply with their timing specifications, with related parameters, for example, exemplified by propagation delay, setup time and hold time, access time, refresh time, and raise/fall time; 5. Binning, for sorting the wafers or chips according to the aforesaid test results; 6. Pattern Programming, for compiling microcode of an algorithm pattern generator (ALPG) in order to process test patterns; and 7. Socket Programming, for compiling and implementing test configuration. The aforesaid description sequence and test contents are not restrictive of various actual burn-in tests, and thus the disclosure is applicable to any other burn-in test items not disclosed herein.

In conclusion, compared with the prior art, the disclosure provides a processor burn-in device capable of performing functional tests, with advantages as follows: 1. dispensing customers nowadays with the need to purchase any new high-frequency test apparatuses or any test apparatuses that come with more burn-in test item functions, allowing the customers to keep using conventional burn-in devices while meeting the need for ever-changing semiconductor test technology with a view to extending the service life of the burn-in devices, as well as meeting the need for high-frequency tests dedicated to devices under test and the need for increasing test items, for example, using signal test boards to provide test signals that have higher frequency to perform tests on devices under test and substitute for the 10 MHz signals provided by conventional test apparatuses; 2. using a compensation mechanism for ensuring that all devices under test receive power supply equally; and 3. using a system-scale, test-oriented signal test board to adjust the types and schedules of different test items in the system to detect as early as possible those devices under test which respond negatively, perform programming anew according to the need for different transmission interfaces, and output control signals corresponding to transmission interfaces, dispensing with the need to change different signal test boards, burn-in boards or burn-in sockets in order to change the devices under test for different transmission interfaces (as otherwise taught by the prior art). Therefore, the burn-in devices of the disclosure enhance test efficiency, achieve greater test signal number/density, optimize PCB layout, enable flexible adjustment and flexible control of configured parameters, meet the need for novel test technology, reduce the test cost incurred by the devices under test, enhance power supply stability, and achieve flexible schedules.

What is claimed is:

1. A burn-in board, comprising:
a plurality of test sockets each configured to receive a device under test and each comprising at least one socket power module; and
at least one signal test board coupled to the burn-in board, being in signal connection with at least one of the plurality of test sockets of the burn-in board, and adapted to receive a signal correlating with a power supply setting,
wherein the signal test board controllably causes the burn-in board to provide power to at least one of the plurality of test sockets according to the signal to perform a test process,
wherein the at least one socket power module has a power compensation mechanism for ensuring that the devices under test receive the power equally.

2. A burn-in board, comprising:
a plurality of test sockets each configured to receive a device under test;
at least one signal test board coupled to the burn-in board, being in signal connection with at least one of the plurality of test sockets of the burn-in board, and adapted to receive a signal correlating with a power supply setting; and
a plurality of socket power modules, wherein the test sockets are each electrically connected to at least one of the socket power modules,
wherein the signal test board controllably causes the burn-in board to provide power to at least one of the plurality of test sockets according to the signal to perform a test process,
wherein the at least one socket power module has a power compensation mechanism for ensuring that the devices under test receive the power equally.

3. The burn-in board of claim 1, wherein the socket power module further has a power detection component configured to detect a power transmitted to the devices under test, and the socket power module adjusts the power transmitted from the socket power module to the devices under test according to a first difference lying between the power transmitted from the socket power module to the devices under test and supply setting of the power and detected by the power detection component.

4. The burn-in board of claim 1, wherein the socket power module is an integrated power module or a power management integrated circuit.

5. The burn-in board of claim 1, wherein the socket power module has a socket detection module electrically connected to the devices under test and the signal test board and configured to detect a power during a test performed on the devices under test, and the signal test board adjusts power supply to the test sockets according to a second difference lying between each of the devices under test and supply setting of the power and detected by the socket detection module, allowing the socket detection module to transmit the second difference to the signal test board.

6. A burn-in system, integrated into a signal test board, the system comprising:
a control unit configured to perform programming according to a plurality of transmission interfaces to output a test signal corresponding to one of the plurality of transmission interfaces and receive a control signal from a signal control system;
a memory unit;
a multiport unit in signal connection with a plurality of test sockets; and
a communication unit in signal connection with the control unit, the memory unit and the multiport unit,
wherein the control unit outputs a test signal to at least one of the plurality of test sockets according to the control signal.

7. A burn-in system, integrated into a signal test board, the system comprising:
a memory unit;
a multiport unit in signal connection with a plurality of test sockets; and
a communication unit being in signal connection with the memory unit and the multiport unit, configured to perform programming according to a plurality of transmission interfaces to output a test signal corresponding to one of the plurality of transmission interfaces, and adapted to receive a control signal from a signal control system,
wherein the communication unit outputs a test signal to at least one of the plurality of test sockets according to the control signal.

8. The burn-in system of claim 6, further comprising a conversion unit configured to be in signal connection with the test sockets of one of the plurality of transmission interfaces.

9. The burn-in system of claim 8, wherein the plurality of transmission interfaces at least comprise one of PCIe, SATA, and USB.
